(19) United States
(12) Patent Application Publication
(10) Pub. No.: US 2023/0029346 A1
(43) Pub. Date: Jan. 26, 2023

(54) SOLID BODY CONSTRUCTION ELEMENT

(71) Applicant: ROLF SIEGEL, WÜRZBURG (DE)

(72) Inventor: ROLF SIEGEL, WÜRZBURG (DE)

(21) Appl. No.: 17/936,869

(22) Filed: Sep. 30, 2022

Related U.S. Application Data
(63) Continuation of application No. PCT/EP2021/058346, filed on Mar. 30, 2021.

(30) Foreign Application Priority Data
Mar. 31, 2020 (DE) 10 2020 002 061.5

(51) Int. Cl. H01L 31/0224; H01L 31/0216; H01L 31/0264

(52) U.S. Cl. CPC H01L 31/022408; H01L 31/02161; H01L 31/0264

(57) ABSTRACT

A solid-state component responds to electromagnetic radiation and may be used as a photovoltaic element, as a photoelectric sensor, as a photocatalyst, or as a power store. The solid-state component has asymmetrical electrodes which face each other and are electron-conductively connected to each other by a semiconductor material and a coating in such a way that an open terminal voltage of 1.8 volts or even more is achieved by acting electromagnetic radiation.

### CROSS-REFERENCE TO RELATED APPLICATION

This application is a continuation, under 35 U.S.C. § 120, of copending International Patent Application PCT/EP2021/058346, filed Mar. 30, 2021, which designated the United States; this application also claims the priority, under 35 U.S.C. § 119, of German Patent Application DE 10 2020 002 061.5, filed Mar. 31, 2020; the prior applications are herewith incorporated by reference in their entireties.

### FIELD AND BACKGROUND OF THE INVENTION

The invention relates to a solid-state component which responds to electromagnetic radiation and which according to specific embodiment may be used as a (thermo)photovoltaic element, as a photoelectric sensor, as a photocatalyst, as a power store or the like.

### SUMMARY OF THE INVENTION

The solid-state component of the invention is defined by the features of the independent claim. It has a cathode K (from which electrons emerge) and an anode A (into which these electrons enter). Mutually opposing faces of the cathode K and of the anode A delimit an interelectrode space EZR. Located in the interelectrode space EZR are a semiconductor material HL and a coating material BM. The semiconductor material HL is configured as an n-type semiconductor nHL and contacts the cathode K and also, preferably, the coating material BM as well. The coating material BM contacts the anode A and also, preferably, the n-type semiconductor nHL as well.

In accordance with the invention the materials used have the following energy positions relative to vacuum:

i) the work function OK of the cathode K is greater than the work function Φ_{A} of the anode A (Φ_{K}>Φ_{A}),
ii) the bandgap E_{gHL} of the n-type semiconductor nHL is greater than 2.0 eV (E_{gnHL}>2 eV) and its Fermi level E_{FnHL} is greater than or (substantially) equal to the work function OK of the cathode K (E_{FnHL}≥Φ_{K}), and
iii) the work function of the coating material BM is less than the work function of the anode A (Φ_{BM}<Φ_{A}) or the coating material BM has a negative electron affinity (NEA).

There is electron-conducting contact between the cathode K, the n-type semiconductor material nHL, the coating material BM, and the anode A, and regions of the cathode (K) and of the anode (A) which are not contacted with the n-type semiconductor material (nHL) or with the coating material (BM) respectively are connectable or—in the operation of the solid state element—connected to one another to form an electrical circuit via current collectors and optionally a consumer.

Preferred embodiments of the invention are elucidated in the dependent claims.

Other features which are considered as characteristic for the invention are set forth in the appended claims.

Although the invention is illustrated and described herein as embodied in a solid body construction element, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a schematic representation showing a solid state component having a cathode K, a semiconductor material HL in the form of an n-type semiconductor nHL, a coating material BM, and an anode A, and also the energy positions (in eV) relative to vacuum of these components in the uncontacted state; and

FIG. 2 is a band graph showing the materials used for the cathode K, the n-type semiconductor nHL, the coating material BM, and the anode A in electron-conducting contacting, under short-circuit conditions and with exposure of the cathode K to electromagnetic energy hv.

### DETAILED DESCRIPTION OF THE INVENTION

In all of the figures, those parts, parameters and structures that correspond to one another are always provided with the same reference symbols.

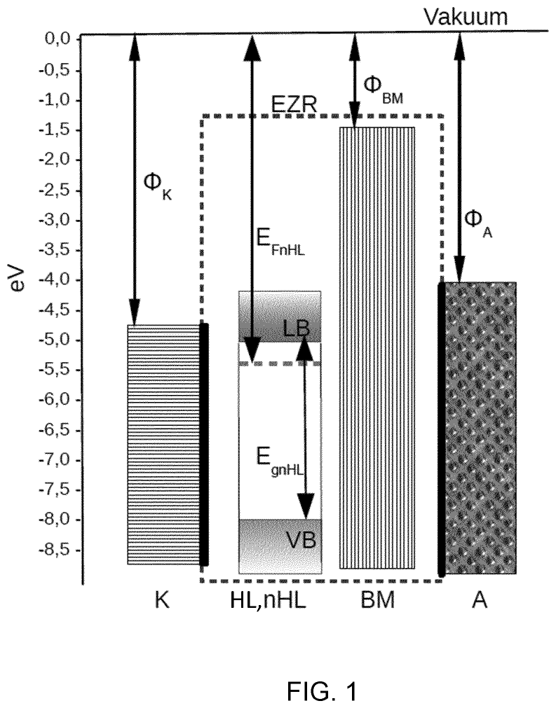

Referring now to the figures of the drawings in detail and first, particularly to FIG. 1 thereof, there is shown schematically the arrangement of the components of a solid state component, specifically: a cathode K, a semiconductor material HL in the form of an n-type semiconductor nHL, a coating material BM, and an anode A relative to one another. FIG. 1 also schematically represents the aforementioned energy positions (in eV) of these components relative to vacuum in the uncontacted state. The mutually opposing faces of the cathode K and of the anode A delimit an interelectrode space EZR.

The cathode K and the anode A are formed of electron-conducting materials which may be present either in elemental form or as alloys. These electrode materials are selected such as to maximize the difference between the work function OK of the cathode K and the work function OA of the anode A.

Nonlimiting examples of suitable cathode materials are:

gold Au (Φ_{Au} 4.8-5.4 eV),
selenium Se (Φ_{Se} 5.11 eV),
platinum Pt (Φ_{Pt} 5.32-5.66 eV),
nickel Ni (Φ_{Ni} 5.0 eV), and
electron-conducting carbon C, e.g., graphite (Φ_{graphite} 4.7 eV).

Nonlimiting examples of electron-conducting carbon C include activated carbon cloth, graphite (in the form of particles, sheetlike textiles, or films), fullerenes, graphene, and carbon nanotubes.

Nonlimiting examples of suitable anode materials are:

magnesium Mg (Φ_{Mg} 3.7 eV),
barium Ba (Φ_{Ba} 1.8-2.52 eV),
cesium Cs (Φ_{Cs} 1.7-2.14 eV),
calcium Ca (Φ_{Ca} 2.87 eV), and
aluminum Al (Φ_{Au} 4.0-4.2 eV).

Depending on the configuration and field of use of the solid-state component, the cathode K and anode A faces forming the interelectrode space EZR may be congruent or (in the mathematical sense) similar and may be dimensioned for example in the range of square micrometers or square meters.

The contact(ing) faces of cathode K and anode A with, respectively, the semiconductor material nHL and coating material BM that are located in the interelectrode space EZR are as large as possible. Depending on configuration and field of use, the thicknesses of the cathode K and of the anode A are different: in the case of a photovoltaic element configuration, for example, a thin, nanometer-thick cathode K of gold (leaf) is used. In the case of configuration as a (thermo)photovoltaic element, the cathode K for example is a micrometer- or millimeter-thick graphite film or is formed of nanometer- or micrometer-sized graphite particles. In the case of configuration as an energy store, the dimensioning of the (porous) electrodes is in the decimeter or liter range.

Suitable n-type semiconductor materials nHL which fulfil the conditions E_{gnHL}>2 eV and E_{FnHL}>F_{K} may be taken for example from the studies by Shiyou Chen and Lin-Wang Wang, Chem. Mater., 2012, 24 (18), pp. 3659-3666 and/or from J. Robertson and B. Falabretti, Electronic Structure of Transparent Conducting Oxides, pp. 27-50 in Handbook of Transparent Conductors, Springer, DOI 10.1007/978-1-4419-1638-9). If graphite (with Φ_{graphite} around 4.7 eV) is used as cathode K, these materials are—as nonlimiting examples—ZnO, PbO, FeTiO₃, BaTiO₃, CuWO₃, BiFe₂O₃, SnO₂, TiO₂, WO₃, Fe₂O₃, In₂O₃ and Ga₂O₃.

The face of the anode A that faces the interelectrode space EZR is coated with a coating material BM whose work function Φ_{BM} is even lower than the work function Φ_{A} of the anode A (Φ_{BM}<Φ_{A}) The invention for this purpose uses alkali metal oxides, alkaline earth metal oxides, rare earth oxide, rare earth sulfides, or binary or ternary compounds consisting thereof. According to literature reports, e.g., V. S. Fomenko and G. V. Samsonov (ed.), Handbook of Thermionic Properties, ISBN: 978-1-4684-7293-6, their work functions (1) are in the range of 0.5-3.3 eV. Compounds of these kinds have to date been used for coating cathode materials of photodetectors, vacuum tubes, thermionic emitters, LEDs or the like in order to facilitate the emergence of electrons from the cathode material. In the present case it is assumed that they facilitate the entry of electrons into the material of the anode A. Additionally, to aforementioned coating material BM whose work function is below the vacuum reference variable, compounds having a work function above vacuum are also used. These are compounds with negative electron affinity (NEA). Examples include hexagonal boron nitride (hBN).

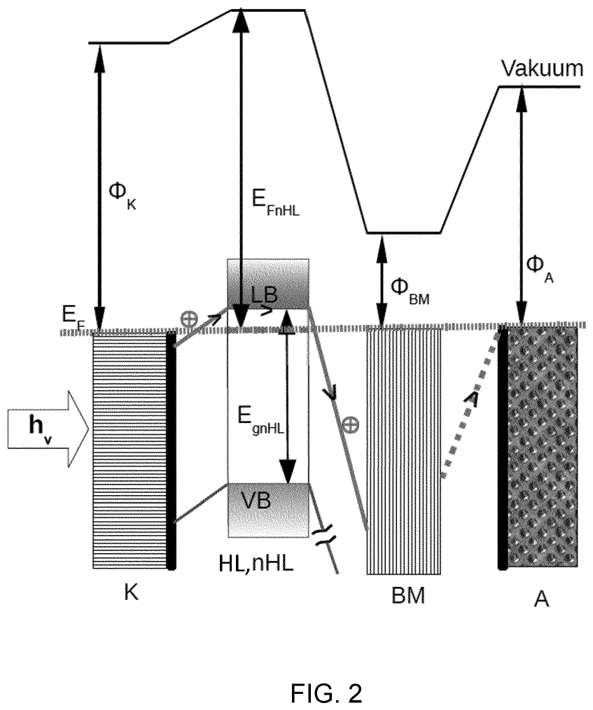

The component of the invention is formed by electron-conducting contacting of materials described above with one another. FIG. 2 shows the mutual energetic relations of the cathode K, of the n-type semiconductor material nHL, of the coating material BM, and of the anode A from FIG. 1 in the short-circuited state. An interface K/nHL formed between the cathode K and the n-type semiconductor material nHL forms a Schottky contact with electron accumulation (labeled with ⊕). For an interface nHL/BM formed between the n-type semiconductor material nHL and the coating material BM, electron accumulation ⊕ is likewise assumed. An interface BM/A formed between the coating material BM and the anode A, conversely, tends to have electrons tunneling through it (denoted by dashed line). These interfaces are not energetic barriers for electrons: even at room temperature and in darkness, they are able to depart the energetically lower cathode K and enter the energetically higher anode A— this is evidenced by a continuous increase in the open circuit voltage V_{OC}; see example 1.

The functioning: by electromagnetic radiation which acts on the cathode K with sufficiently great energy, electrons in the volume of the cathode material are excited—directly or indirectly via phonons and plasmons—in such a way that they are capable of departing the cathode material and enter into the conduction band of the n-type semiconductor material nHL, this being (readily) possible because of the electron accumulation ⊕ existing at the K/nHL interface. If the electrons continue to have sufficient (kinetic) energy, they pass via the nHL/BM interface into the volume of the coating material BM, before then entering across the BM/A interface into the volume of the energetically higher anode A. Because the n-type semiconductor material nHL has a bandgap E_{gHL} of more than 2 eV, there is no recombination with holes from the valence band.

For the operation of the solid-state component, portions of the cathode K that are free of n-type semiconductor and portions of the anode A that are free of coating material are connected by one or more electrical conductors and optionally an electrical consumer connected between them, to form an electrical circuit. The stated electrical conductor or conductors and the consumer which is optionally present form an external part of the electrical circuit, one not belonging to the solid-state component of the invention. In this operating state of the solid-state component, electrons which are “hot” enough are able to perform electrical work, since they flow back from the energetically higher anode A via the external portion of the electrical circuit to the cathode K. Accordingly the component is also suitable, among other things, as a (thermo)photovoltaic cell for converting heat energy into electrical energy.

For the respective electron-conducting contacting of the materials used it is possible to employ known (semiconductor) technologies such as spin coating, (electrostatic) fixing of (nano)crystals, sputtering, atomic layer deposition (ALD), epitaxy, chemical vapor deposition (CVD), physical vapor deposition (PVD), chemical bath deposition (CBD) or (electro)chemical methods.

Parameters such as, for example, contacting conditions (temperature, pressure, gas atmosphere, humidity, pH of solutions), stoichiometric composition of the electrode and/or semiconductor materials, their roughness, their position in the thermoelectric or electrochemical voltage series, formation of (dipole) layers, crystal size, crystal face orientation, crystallinity, (fraction of) water of crystallization, nature and extent of lattice defects, nature and extent of doping, lattice adaptation, layer morphology, thickness of applied layer(s), their porosity, etc., are familiar to the skilled person, can be varied within wide ranges, and can be optimized (on the basis of experimental results obtained).

### Example 1

Materials used:

The material for the cathode K is graphite with a work function Φ_{K} of 4.7 eV.

The material for the anode A is magnesium with a work function Φ_{A} of 3.7 eV.

The coating material BM for the anode A is barium oxide with a work function Φ_{BM} of 1.9 eV.

The n-type semiconductor material nHL is tin(IV) oxide SnO₂.

In accordance with the literature, the assumptions are an energy position of the conduction band LB of 5.1 eV, a Fermi level E_{Fsno2} of 5.3 eV, an energy position of the valence band VB of 8.6 eV, and a bandgap E_{gSnO2} of 3.5 eV.

Production of the component:

Electron-conducting contacting of the cathode K with the n-type semiconductor material nHL.

Activated carbon cloth (FLEXSORB FM30K) from Chemviron Cloth Division, Tyne & Wear (UK) is fully covered with a solution of around 2.0% (w/v) Sn(II)Cl₂*2H₂O in 70% (v/v) 2-propanol solution in water over 5 hours. Following removal of excess solution, one side of the wet cloth is exposed to an ammonia atmosphere for around 12 hours. The cloth is subsequently dried at around 50° C. over a number of hours. The resulting layer, which has a silvery luster, comprises (cassiterite) crystals of tin(IV) oxide SnO₂.

Electron-conducting contacting of the anode A with the coating material BM.

A portion around 17 mm long of a 20×3.2×0.3 mm magnesium tape is immersed for around 2 seconds in 1N hydrochloric acid, with the adhering oxide layer being removed with evolution of hydrogen. After drying with a soft paper towel, around 10 μl of a saturated aqueous barium oxide solution with a temperature of around 90° C. is trickled using a pipette onto the acid-contacted portion. Thereafter the tape, with the treated side upward, is heat-treated at an estimated temperature of around 900° C. on a glassy carbon plate lying atop a Bunsen burner for around 30 min. The resulting layer, which is gray in color, contains barium oxide BaO.

Assembly to form the solid-state component.

The anode A produced under II) is fastened by the untreated side to a self-adhesive tape (Tesafilm®). The cathode K produced under I) is fastened by the side with a silvery luster on the anode A congruently in such a way that the end not treated with hydrochloric acid and also around 2 mm of the gray-colored BaO layer remain bare, leading to an electron-conducting contact face of the anode A that measures around 15×3.2 mm. As a cathodic current collector, a copper wire 0.1 mm thick is fastened by means of adhesive tape (Tesafilm®) on the activated carbon cloth; the anodic current collector is the end of the magnesium tape not contacted with hydrochloric acid—the oxide layer present here is additionally removed mechanically.

The component thus produced is then placed between two glass slides, the size of the upper slide being such as to allow the aforementioned current collectors to be connected to leads of a multimeter. The electron-conducting contacting of the cathode K with an anode A is made by compressing and fastening the two slides by means of clips. In order further to increase ease of handling and stability of the component, it can be introduced into an optically clear 2K epoxy casting compound, with the current collectors being left bare, the casting compound then being cured. The component thus produced is integrated into an electrical circuit by connecting the (cathodic) copper wire to the positive terminal of a multimeter and the free end of the (anodic) magnesium tape to the negative terminal.

Measurements of the short-circuit current I_{SC}, at room temperature with ambient light, consistently produce values of 5 μA/cm². In sunshine, through the focal spot of a magnifying glass directed onto the cathode K, values of around 2000 μA/cm² are achieved. Where the open circuit voltage V_{OC} is measured immediately after an I_{SC} measurement of this kind, V_{OC} values of around 0.7 volt are obtained. Even at room temperature and in darkness, there is in that case, within around eight hours, an increase in the V_{OC} value to around 1.8 volts. Where an I_{SC} measurement is performed at the maximum V_{OC} value, current values of 400 μA/cm² are initially obtained, and then drop continuously over the course of around 20 min to values of around 20 μA/cm². The component is therefore suitable as an energy store, including, among other forms, in the form of a self-charging capacitor.

The open circuit voltage V_{OC} of the component (cast in epoxy) is constant at around 1.8 volts for months, and this is also reflected in a lack of corrosion of the anode A.

The above-stated sizing of cathode K and anode A is retained for the following examples.

### Example 2

The n-type semiconductor nHL used is TiO₂. Energy positions: conduction band LB 4.6 eV; Fermi level E_{FTio2} 5.3 eV; valence band VB 7.8 eV; and bandgap E_{gTiO2} 3.7 eV. The activated carbon cloth (cathode K) is impregnated with a 1% (v/v) solution of titanium(IV) ethoxide in 2-propanol and dried at 90° C. for several days. Anode A and coating material BM as in example 1. Contacting of the activated carbon cloth (colored white as a result of formation of TiO₂) with BaO-coated anode A and assembly as described in example 1. Results of measurement as in example 1.

### Example 3

The n-type semiconductor nHL used is Fe₂O₃. Energy positions: conduction band LB 5.0 eV; Fermi level E_{FFe2O3} 5.3 eV; valence band VB 7.3 eV; and bandgap E_{g} Fe₂O₃ 2.3 eV. Anode A and coating material BM as in example 1. Application of around 10 μl of an aqueous, saturated solution of Fe(III) nitrate to the coating face of BaO. Initially drying at room temperature and thereafter heat treatment as in example 1. Contacting with unmodified activated carbon cloth (cathode K) and assembly as in example 1. Results of measurement as in example 1.

### Example 4

The coating material BM used is calcium oxide CaO. Cleaning of the anode, again consisting of magnesium, as in example 1. Application of around 10 μl of an aqueous, saturated solution of calcium nitrate Ca(NO₃)₂ to the cleaned magnesium surface and subsequent heat treatment at around 900° C. Thereafter application of around 10 μl of an aqueous, saturated solution of Fe(III) nitrate to the coating face of CaO to form the semiconductor layer of Fe₂O₃ (in analogy to example 3). Initially drying at room temperature and thereafter heating as in example 1. Contacting with untreated activated carbon cloth and assembly as in example 1. Results of measurement as in example 1.

### Example 5

The coating material BM used is strontium oxide SrO. Cleaning of the anode A, again consisting of magnesium, as in example 1. Application of around 10 μl of an aqueous, saturated solution of strontium nitrate Sr(NO₃)₂ to the cleaned magnesium surface and subsequent heat treatment at around 900° C. Thereafter application of around 10 μl of an aqueous, saturated solution of Fe(III) nitrate to the coating face with SrO to form the semiconductor layer of Fe₂O₃ (in analogy to example 3). Initially drying at room temperature and thereafter heating as in example 1. Contacting with untreated activated carbon cloth (cathode K) and assembly as in example 1. Results of measurement as in example 1.

### Example 6

The coating material BM used is cesium oxide Cs₂O. Cleaning of the anode A, again consisting of magnesium, as in example 1. Dissolving of a spatula tip of cesium iodide Csl in around 10 ml of dilute KOH. Application of 10 μl to the cleaned magnesium surface and subsequent heat treatment at around 900° C. Thereafter application of around 10 μl of an aqueous, saturated solution of Fe(III) nitrate to the coating face with Cs₂O to form the semiconductor layer of Fe₂O₃ (in analogy to example 3). Initially drying at room temperature and thereafter heating as in example 1. Contacting with untreated activated carbon cloth and assembly as in example 1. Results of measurement as in example 1.

### Example 7

The coating material BM used is hexagonal boron nitride hBN. Cleaning of the anode A, again consisting of magnesium, as in example 1. Dispersing of a spatula tip of hBN in around 10 ml of ethyl acetate. Application of 10 μl of the dispersion to the cleaned magnesium surface; after evaporation of ethyl acetate, heat treatment at around 900° C. over 30 min. Thereafter application of around 10 μl of an aqueous, saturated solution of Fe(III) nitrate to the coating face with hBN to form the semiconductor layer of Fe₂O₃ (in analogy to example 3). Initially drying at room temperature and thereafter heating as in example 1. Contacting with untreated activated carbon cloth and assembly as in example 1. Results of measurement as in example 1.

In summary, in the solid state component, mutually opposing asymmetrical electrodes, namely the cathode K and the anode A, are connected to one another with electron conduction, by means of a semiconductor material HL and a coating material BM, in such a way that exposure to electromagnetic radiation produces an open circuit voltage V_{OC} of around 1.8 volts or even more.

1. A solid state component, comprising:
a cathode being exposable to electromagnetic radiation;
an anode;
an interelectrode space being formed by opposing faces of said cathode and said anode;
a semiconductor material disposed in said interelectrode space; and
a coating material disposed in said interelectrode space;
wherein for achieving an electron flow between said cathode and said anode:
a work function of a cathode material is greater than a work function of an anode material;
said semiconductor material contacts said cathode in said interelectrode space and is an n-type semiconductor material whose bandgap is greater than 2.0 eV and whose Fermi level position is not less than the work function of said cathode;
said coating material contacts said anode in said interelectrode space, and said coating material has a work function which is less than the work function of said anode, or said coating material has a negative electron affinity;
there is electron-conducting contact between said cathode, said n-type semiconductor material, said coating material, and said anode; and
regions of said cathode and of said anode which are not contacted with said n-type semiconductor material or with said coating material respectively are connectable to one another to form an electrical circuit via current collectors.

2. The solid-state component according to claim 1, wherein said cathode material is electron-conducting carbon.

3. The solid-state component according to claim 1, wherein said anode material is magnesium or a magnesium alloy.

4. The solid-state component according to claim 1, wherein said coating material is an alkali metal oxide, an alkaline earth metal oxide, a rare earth oxide, a rare earth sulfide or is a binary or ternary compound consisting thereof, or a material having negative electron affinity.

5. The solid-state component according to claim 1, wherein said coating material is barium oxide BaO, calcium oxide CaO, strontium oxide SrO, cesium oxide Cs₂O or hexagonal boron nitride hBN.

6. The solid-state component according to claim 1, wherein said n-type semiconductor material is ZnO, Fe₂O₃, PbO, FeTiO₃, BaTiO₃, CuWO₃, BiFe₂O₃, SnO₂, TiO₂, WO₃, In₂O₃ or Ga₂O₃.

7. The solid-state component according to claim 1, wherein said regions of said cathode and of said anode which are not contacted with said n-type semiconductor material or with said coating material respectively are connectable to one another to form said electrical circuit via said current collectors and a consumer.
